(19) United States
(12) Patent Application Publication
(10) Pub. No.: US 2009/0321805 A1
(43) Pub. Date: Dec. 31, 2009

(54) INSULATOR MATERIAL OVER BURIED CONDUCTIVE LINE

(75) Inventors: Johannes von Kluge, Dresden (DE); Arnd Scholz, Dresden (DE); Joerg Radecker, Dresden (DE); Matthias Patz, Dresden (DE); Stephan Kudelka, Radebeul (DE); Alejandro Avellan, Dresden (DE)

Correspondence Address: ESCHWEILER & ASSOCIATES LLC, NATIONAL CITY BANK BUILDING, CLEVELAND, OH, 44114, US

(73) Assignee: Qimonda AG, Muenchen (DE)

(21) Appl. No.: 12/165,072

(22) Filed: Jun. 30, 2008

(51) Int. Cl. H01L 27/108; H01L 29/78; H01L 21/28; H01L 21/4763

(52) U.S. Cl. 257/302; 257/330; 438/591; 438/675; 257/E27.084; 257/E29.262; 257/E21.177; 257/E21.495

(57) ABSTRACT

One embodiment relates to an integrated circuit that includes a conductive line that is arranged in a groove in a semiconductor body. An insulating material is disposed over the conductive line. This insulating material includes a first insulating layer comprising a horizontal portion, and a second insulating layer that is disposed over the first insulating layer. Other methods, devices, and systems are also disclosed.

### FIELD OF INVENTION

The present invention relates generally to semiconductor devices and more particularly to improved methods and systems for semiconductor memories.

### BACKGROUND OF THE INVENTION

Several trends presently exist in the semiconductor and electronics industry. One trend is that recent generations of portable electronic devices are using more memory than previous generations. This increase in memory allows these new devices to store more data, such as music or images, and also may provide the devices with more computational power and speed.

One type of memory device includes an array of memory cells, where each cell includes a capacitor that stores data. Depending on the amount of charge stored in the capacitor, the capacitor can be switched between two or more states (e.g., a high-charge state and a low-charge state). In real world-implementations, the high-charge state can be associated with a logical “1” and the low-charge state can be associated with a logical “0”, or vice versa. Additional charge states could also be defined to implement a multi-bit cell with more than two states per cell. Therefore, by switching between these states, a user can store any combination of “1”s and “0”s in the array, which could correspond to digitally encoded music, images, software, etc.

### SUMMARY OF THE INVENTION

One embodiment relates to an integrated circuit that includes a conductive line that is arranged in a groove in a semiconductor body. An insulating material is disposed over the conductive line. This insulating material includes a first insulating layer comprising a horizontal portion, and a second insulating layer that is disposed over the first insulating layer. Other methods, devices, and systems are also disclosed.

### BRIEF DESCRIPTION OF THE DRAWINGS

FIG. 1 shows one embodiment of a memory array that includes buried wordlines;

FIG. 2 shows a cross-sectional view of a memory cell taken along the cross-section line of FIG. 1;

FIG. 3 shows a cross-section view of a memory cell in which voids or seams are present in the dielectric cap;

FIG. 4 shows a flowchart for a first embodiment in accordance with some aspects of the present invention;

FIGS. 5 through 10A, 10B show cross sectional views at various manufacturing stages consistent with FIG. 4's embodiment;

FIG. 11 shows a flowchart for a second embodiment in accordance with some aspects of the present invention;

FIGS. 12 through 20 show cross sectional views at various manufacturing stages consistent with FIG. 11's embodiment;

FIG. 21 shows a flowchart for a third embodiment in accordance with some aspects of the present invention; and

FIGS. 22 through 26 show cross sectional views at various manufacturing stages consistent with FIG. 21's embodiment.

### DETAILED DESCRIPTION OF THE INVENTION

One or more implementations of the present invention will now be described with reference to the attached drawings, wherein like reference numerals are used to refer to like elements throughout. The drawings are not necessarily drawn to scale.

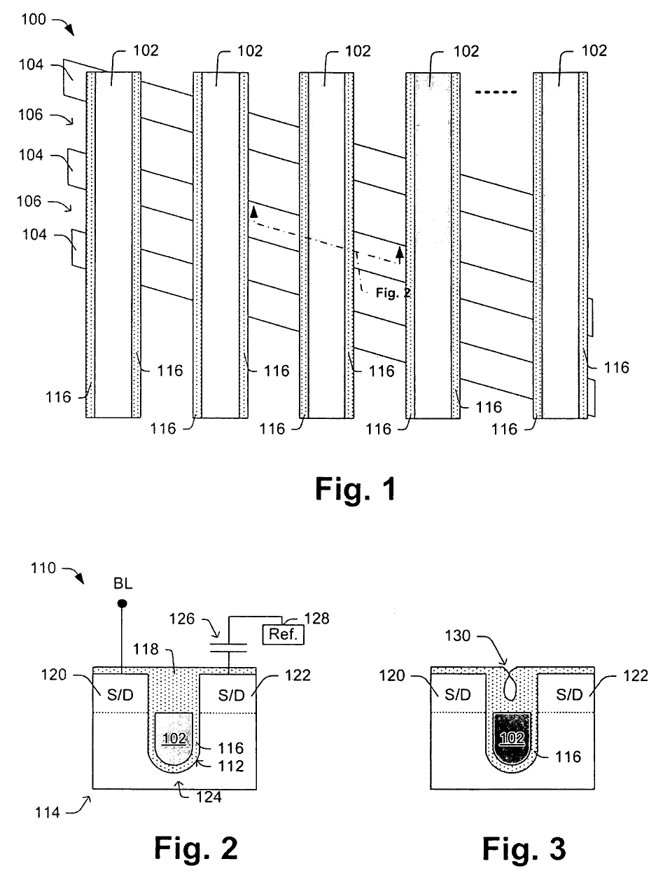

FIG. 1 shows a portion of a memory array 100 in accordance with some aspects of the present invention. In FIG. 1, a plurality of buried conductive wordlines 102 are formed along a first direction. Active area lines 104 are often disposed at a slanted angle with respect to the conductive wordlines 102. Isolation regions 106 (e.g., shallow trench isolation (STI) regions) separate adjacent active area lines from one another. In addition, a plurality of conductive bitlines (not shown) are formed along a second direction, which is often perpendicular to the first direction.

FIG. 2 shows a cross-sectional view of a memory cell 110, taken along the cross-sectional line from FIG. 1. The memory cell 110 includes a conductive wordline 102 disposed in a groove 112 in a semiconductor body 114. A gate insulating layer 116 is disposed in the groove to electrically isolate the conductive wordline 102 from the active area 104, and a continuous dielectric cap 118 is formed over the conductive wordline 102. Source/drain regions 120, 122, which have a first doping type (e.g., n-type), are disposed in the active area 104. A channel region 124, which has a second doping type that is opposite the first doping type (e.g., p-type), is disposed between the source/drain regions 120, 122 under the lower surface of the groove 112.

To access a row of memory cells (which includes the memory cell 110), a memory controller asserts the conductive wordline 102. This frees electrical carriers from the semiconductor lattice in the channel region 124, thereby electrically coupling the bitline BL to the memory cell's storage capacitor 126. While the row is accessed, the storage capacitors of the accessed cells can be written to or read from.

For a write operation, the memory controller asserts or de-asserts the bitline BL (relative to a reference potential 128) while the conductive wordline 102 is asserted. This causes charge to flow to or from the bitline BL, through the channel region 124, and to or from the accessed capacitor 126. Thus, a predetermined amount of charge corresponding to a “1” or “0” can be “written” to the accessed capacitor 126. After this write operation, the conductive wordline 102 is de-asserted, which tends to store the charge in the capacitor 126 for later read operations. Because charge may leak from the capacitor 126, refresh operations may be needed periodically.

For a read operation, the memory controller asserts the conductive wordline while the BL floats, causing some amount of charge to leak from the accessed capacitor 126 onto the bitline BL. A sense amp (not shown) could determine the bit value stored in the capacitor 126, for example, by comparing the charge on the bitline BL (e.g., a voltage or current on the bitline) to that of a similar bitline of a reference cell. Depending on how the charge on the bitline BL compares to the reference cell, the memory cell 110 will be deemed to have a “1” or “0” stored therein. Because read operations change the charge in the storage capacitor 126 (i.e., reads are “destructive”), it may be beneficial to write back read values to the capacitor 126 after a read access.

While FIGS. 1-2 set forth a memory device that includes a U-shaped conductive wordline 102, conductive wordlines could have other shapes as well. For example, V-shaped, W-shaped, rectangular, square, and other shaped conductive wordlines are also contemplated as falling within the scope of the present invention. By being buried in the semiconductor body 114, the conductive wordlines allow for a longer gate length within a smaller die area (relative to a planar device), while still providing comparable device characteristics. This facilitates high density memory arrays, which allow users to store a large amount of data in a small area.

Several unique challenges arise when one attempts to manufacture a device with buried conductive lines. For example, as the inventors have appreciated and as is shown in FIG. 3, unless adequate procedures are employed, voids or seams 130 may occur in the dielectric cap 118. These voids or seams may cause reliability problems during the lifetime of the memory device. Other problems may also be experienced, but are omitted for purposes of clarity and succinctness.

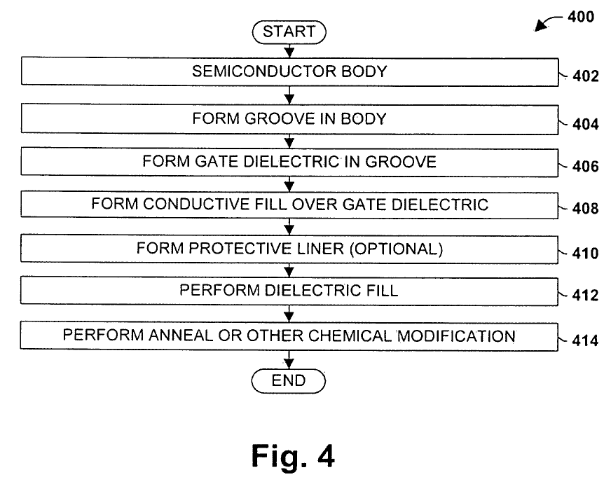

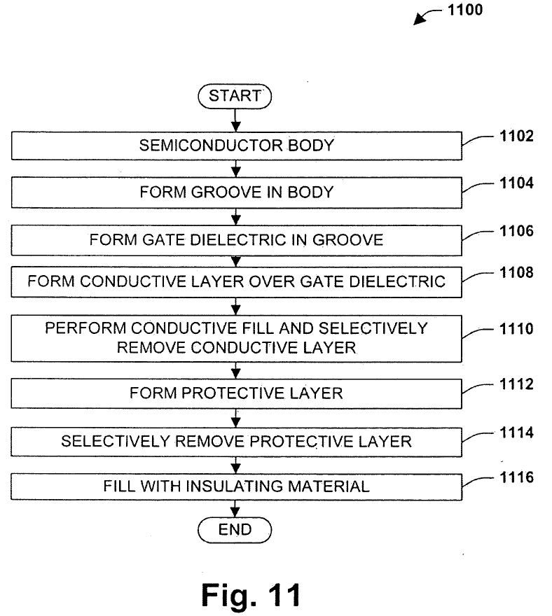

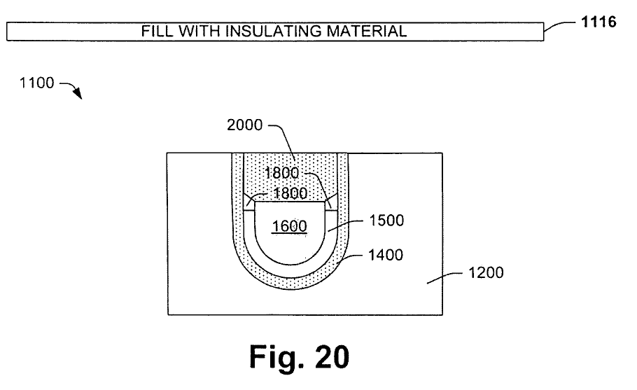

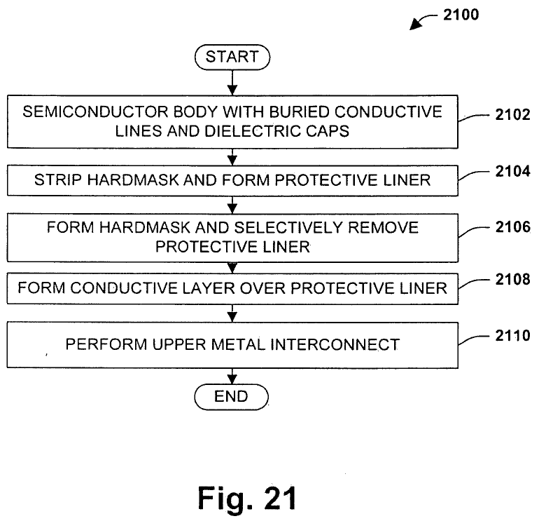

Therefore, the inventors have fashioned memory devices with buried conductive lines and methods of manufacturing these devices. In the following detailed description, three manufacturing flows are shown. FIGS. 4-10B show a first process flow, FIGS. 11-19 relate to a second process flow, and FIGS. 20-23 relate to a third process flow. As one of ordinary skill in the art will appreciate, these methods may be combined in various ways, and also encompass other methods where the acts are carried out in different orders. In addition, for purposes of simplicity, these process flows do not necessarily include all process steps. For example, STI formation and source/drain implantation are not shown, among others.

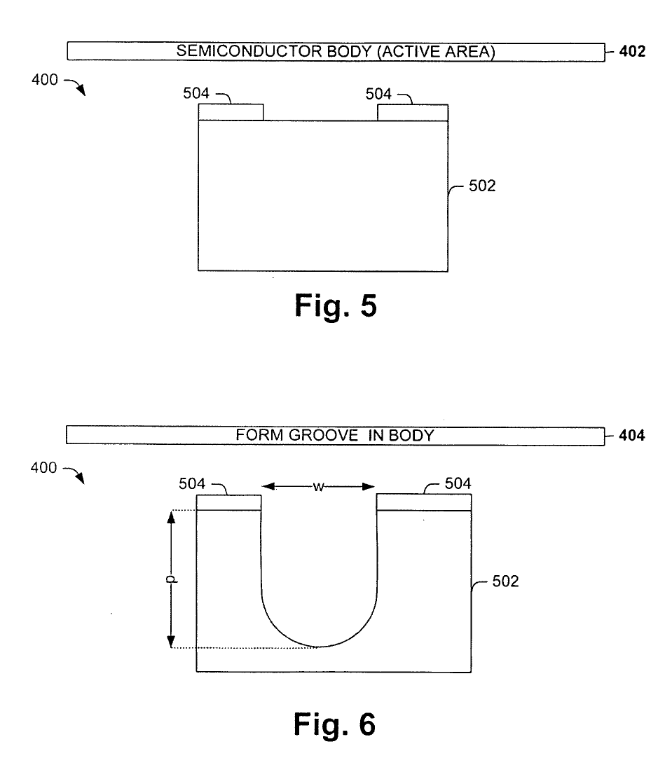

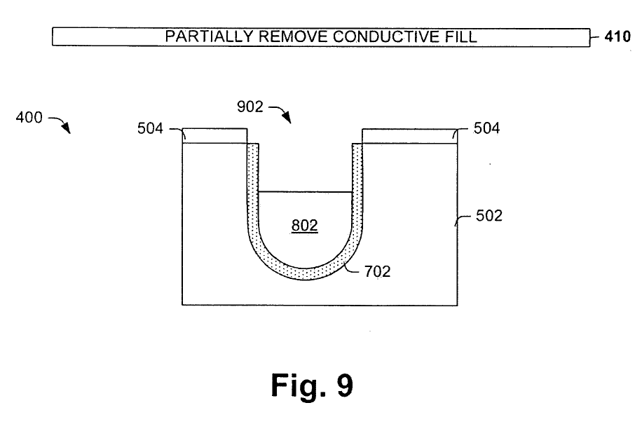

FIG. 4 shows a method 400 where a seamless and voidless dielectric fill is used to form a dielectric cap over a buried wordline. More detailed examples of this method will now be described with reference to the cross-sectional diagrams in FIGS. 5 through 10A, 10B, wherein 10A and 10B show slightly different methodologies that follow FIG. 9.

In FIG. 5 (402) a semiconductor body 502 is provided. The semiconductor body 502 is doped (e.g., via ion implantation or epitaxial formation) to constitute an active area and may include STI regions. A hardmask is formed and patterned over the semiconductor body 502 to cover some regions of the semiconductor body and expose other regions of the semiconductor body. In some embodiments, the composition of the hardmask could be SiN

It will be appreciated that the semiconductor body 502 may comprise a simple Si substrate or any other type of semiconductor body, which may include non-semiconductor materials (e.g., oxide in SOI, partial SOI substrate, polysilicon, amorphous silicon, organic materials). Thus, the semiconductor body may include semiconductor/non-semiconductor and/or deposited or grown (e.g. epitaxial) layers formed on a semiconductor substrate and/or otherwise associated therewith.

In FIG. 6, a groove 602 has been formed in the semiconductor body 502. In some embodiments, the groove could be formed by reactive ion etching. In some embodiments, the groove could have a width, w, ranging from approximately 25 nm to approximately 100 nm. In these and other embodiments, the groove could have a depth, d, ranging from approximately 100 nm to approximately 400 nm.

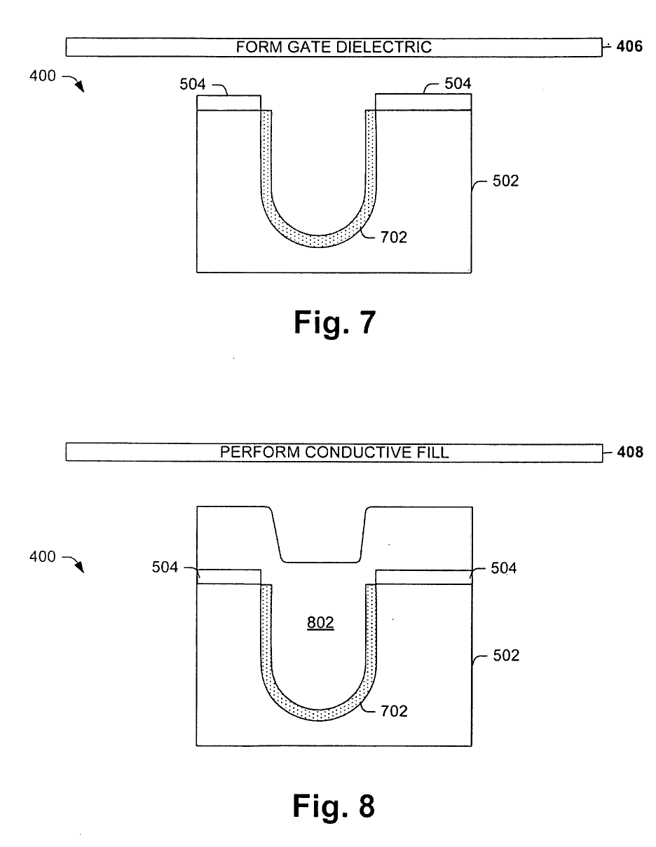

In FIG. 7, a gate insulating layer 702 is conformally formed along sidewalls of the groove. This gate insulating layer 702 could comprise Silicon dioxide (SiO₂), spin-on-dielectric, or other types of dielectric. The gate insulating layer 702 is often relatively thin, and could for example, have a thickness ranging from approximately 2 nm to approximately 10 nm in some embodiments.

In FIG. 8, a conductive fill 802 is formed over the gate insulating layer 702. In some embodiments, the conductive fill material could comprise W, Ti, TiN, or other Ti-based materials, but could also comprise other conductive fill materials such as polysilicon.

In FIG. 9, the conductive fill is partially removed to form a recess 902 extending below the upper surface of the semiconductor body 502. In some embodiments, this partial removal could be achieved by reactive ion etching or wet etching.

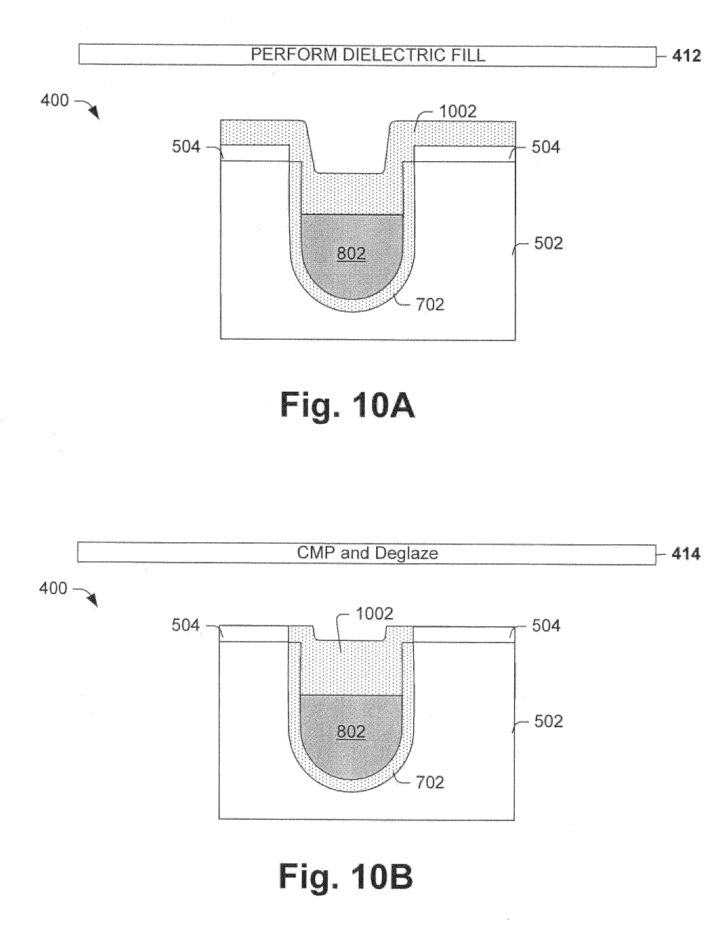

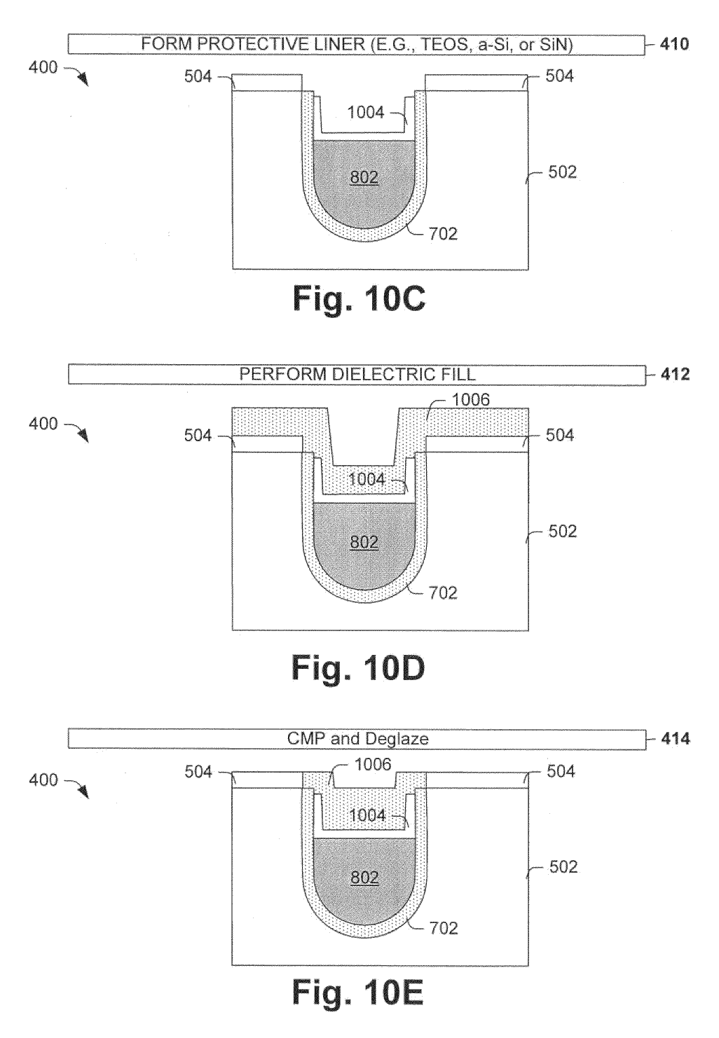

FIGS. 10A-1 through 10A-2 show one manner for filling the recess. In FIG. 10A-1, a dielectric cap 1002 without voids or seams is formed over the conductive fill 802. This can be accomplished in several ways. For example, for small aspect ratios, a high-density plasma (HDP) fill process can be used to form the dielectric cap 1002. For larger aspect ratios, a multi-step procedure can be used. In this multi-step process, HDP is used to partially fill the recess 902 to form a first insulating layer, then the HDP filled first insulating layer is partially etched away. Next, HDP is used to partially fill the recess slightly more than the first HDP fill, thereby forming a second insulating layer. This second insulating layer is then partially removed, another partial fill is performed, and so on. The number of steps in this multi-step process depends on the aspect ratio of the recess 902, as well as other factors. In other embodiments, the void and seamless fill could be accompanied by applying a spin-on-dielectric, or could be formed by performing a bottom-up selective oxide (SELOX) procedure. In FIG. 10A-2, chemical mechanical polishing (CMP) has been performed to planarize the resulting structure, and a deglaze process has also been performed.

FIGS. 10B-1 through 10B-3 depict another embodiment for filling the recess 902. In FIG. 10B-1, a first insulating layer 1004 is formed in the recess 902. This first insulating layer 1004 prevents or limits damage to the conductive fill 802 and/or active area. In some embodiments, the first insulating layer 1004 comprises TEOS, amorphous Si (a-Si), or SiN, among others. In 10B-2, a seamless dielectric cap 1006 is formed. The seamless dielectric cap 1006 could be formed by any of the acts discussed with respect to FIG. 10A-1 above, including a multi-step process. However, if the SELOX procedure is used, an etch is performed to remove the first insulating layer 1004 from the bottom of the groove, so an area of the conductive fill will be exposed for the SELOX procedure. In FIG. 10B-3, a CMP and deglaze are again performed.

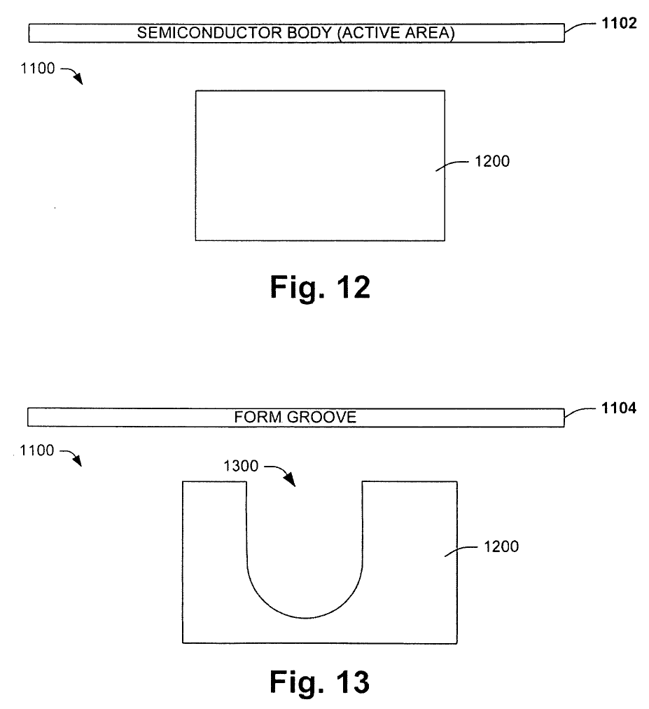

Referring now to FIG. 11, one can see another embodiment of a method that includes forming a conductive line. In this embodiment the conductive line includes a conductive filling and a first conductive layer disposed between the conductive filling and the gate insulating layer. Although FIG. 11 shows a somewhat general embodiment, a more detailed embodiment will now be discussed with respect to the cross sectional drawings in FIGS. 12-20.

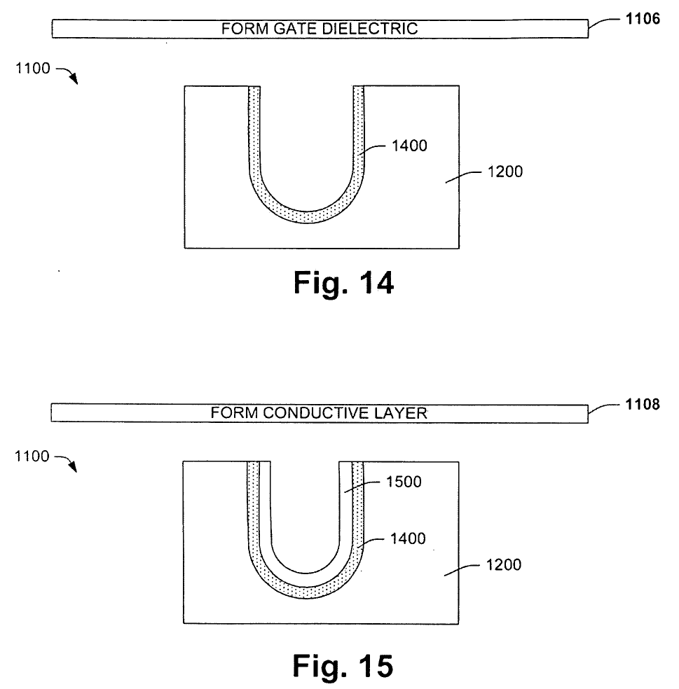

FIGS. 12-14 are similar to FIGS. 5-7 previously discussed. In FIG. 12 (1102) a semiconductor body 1200 is provided, which often includes doped (active) areas and STI regions. In FIG. 13 (1104), a groove 1300 has been formed in the semiconductor body 1200. In FIG. 14, a gate insulating layer 1400 is conformally formed in the groove 1300.

In FIG. 15, a first conductive layer 1500 is formed over the gate insulating layer 1400. In some embodiments, the composition of the first conductive layer 1500 could comprise TiN or poly-silicon.

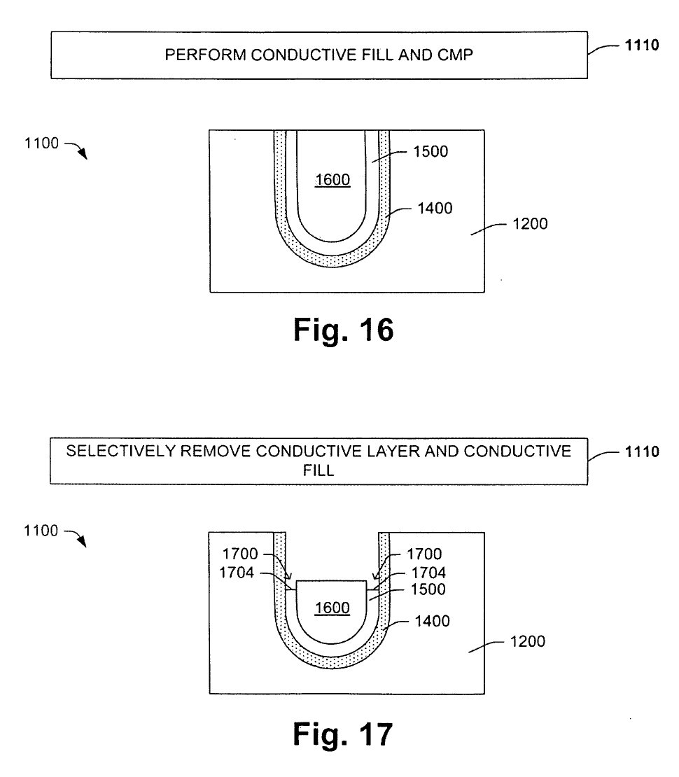

In FIG. 16, a conductive fill 1600 has filled the remainder of the groove, and CMP has been used to planarize the upper surface of the structure. In one embodiment, the conductive fill 1600 can comprise W or poly-silicon. Thus, in some embodiments, the first conductive layer 1500 and conductive fill 1600 can have different compositions, possibly having different etch rates.

In FIG. 17, the first conductive layer 1500 and the conductive fill 1600 are selectively removed. In embodiments where the first conductive layer 1500 has a higher etch rate than the conductive fill 1600, an edge recess 1700 may be formed, such that the conductive fill 1600 has an upper surface 1702 that is above an upper surface 1704 the first conductive layer 1500.

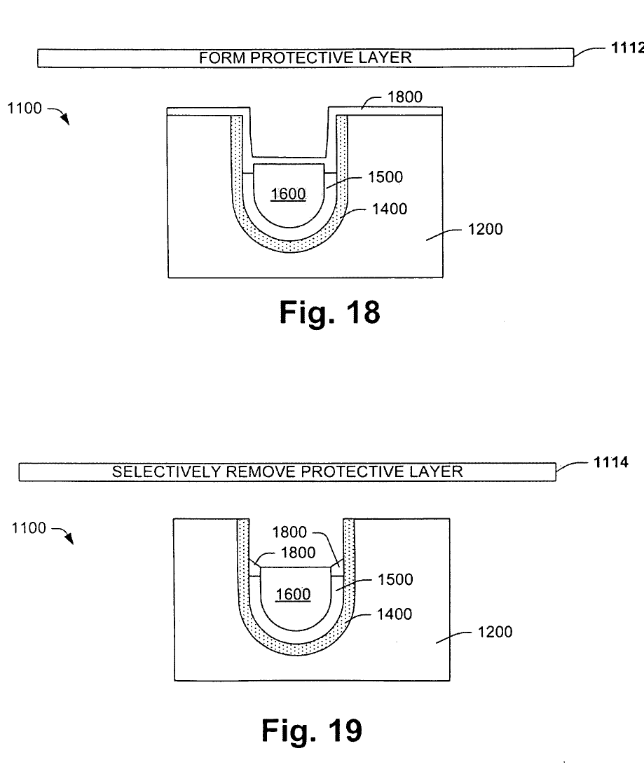

In FIG. 18, a first insulating layer 1800 is formed to extend over the upper surfaces 1702, 1704 of the conductive fill and first conductive layer.

In FIG. 19, the first insulating layer 1800 is selectively removed. This selective removal causes the first insulating layer 1800 to extend over the upper surface of the first conductive layer 1500 but not cover the upper surface of the conductive fill 1600. Due to this configuration, the first insulating layer 1800 acts as a protective barrier during subsequent processing.

In FIG. 20, a voidless and seamless dielectric fill is performed to form a dielectric cap 2000. In some embodiments, this voidless and seamless dielectric fill could comprise any of the acts discussed with respect to FIG. 10A-1 above, including a multi-step process, and could also comprise the use of a protective liner as shown in FIG. 10B-1 (in addition to the first insulating layer 1800), among others.

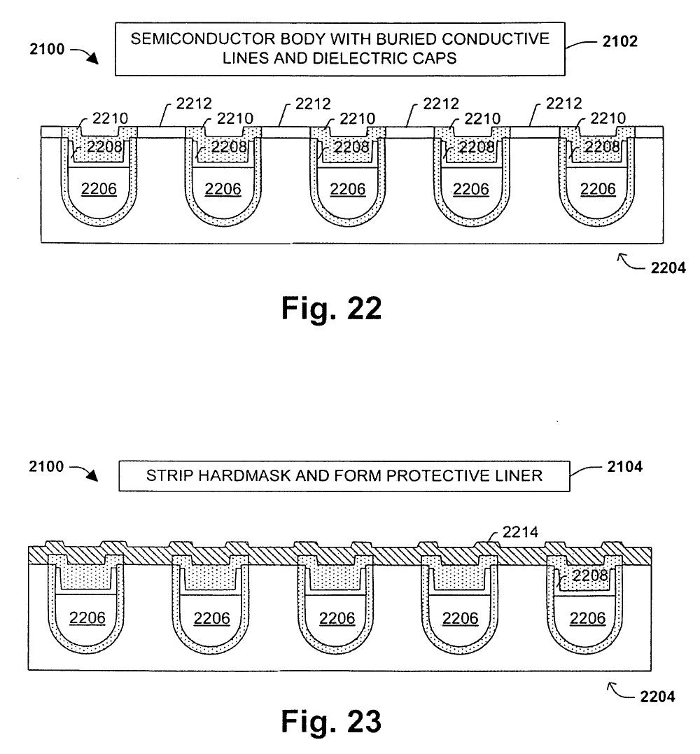

FIG. 21 shows one manner of forming contacts to the active source/drain active region. To limit damage to the buried conductive lines and/or active areas, a protective liner is formed over the dielectric cap and over the tops of silicon pillars. Although FIG. 21 shows a somewhat general embodiment, a more detailed embodiment will now be discussed with respect to the cross sectional drawings in FIGS. 22-28.

FIG. 22 (2102) depicts a series of conductive lines 2202 that are disposed in a semiconductor body 2204. Although this illustrated embodiment is shown with conductive fill 2206, a first insulating layer 2208, and a second insulating layer 2210 (as shown in FIG. 10A); the following process is also applicable to the other previously discussed embodiments (e.g., FIG. 10B, FIG. 20). For purposes of illustration, five conductive lines are shown, but aspects of the invention are applicable to any number of such conductive lines.

In FIG. 23 (2104), the hardmask 2312 is stripped and a protective liner 2214 has been formed over the structure. This protective liner 2214 serves to limit damage to the buried conductive lines and/or active areas. In one embodiment, for example, the protective liner 2214 is a TEOS layer having a thickness of approximately 8 nm.

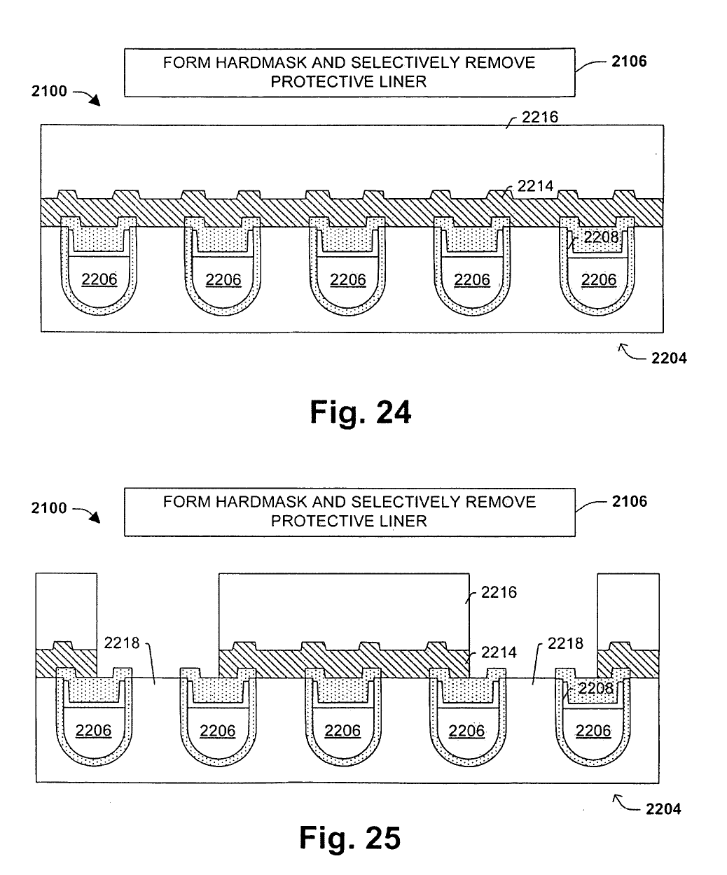

In FIG. 24 (2106), another hardmask 2216 is formed over the protective liner 2214. In FIG. 25 (2106), the hardmask and protective line are patterned and etched to expose some, but not all, of the silicon pillars (e.g., silicon pillars 2218 are exposed).

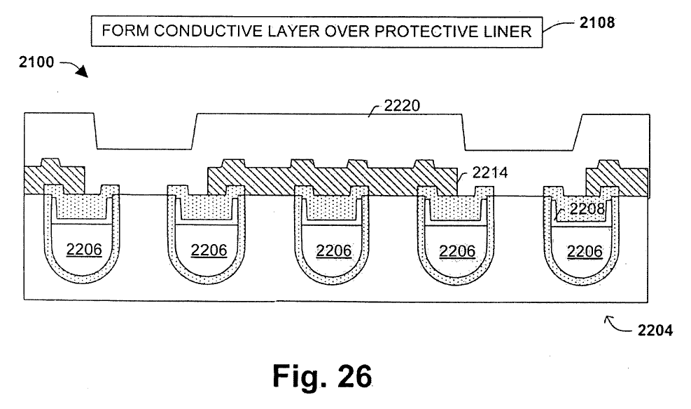

In FIG. 26 (2108), a conductive layer 2220, such as amorphous silicon or polysilicon, is formed over the exposed silicon pillars 2218. This conductive layer 2220 will often serve as a bitline contact to the silicon pillars 2218. In subsequent steps (not shown), additional patterning, etching, and fills, can be used to fashion additional interconnect layers (e.g., metal layers).

While the invention has been illustrated and described with respect to one or more implementations, alterations and/or modifications may be made to the illustrated examples without departing from the spirit and scope of the appended claims. For example, although conductive lines discussed above have been illustrated and discussed with respect to buried wordlines, in other embodiments the conductive lines could also relate to buried bitlines or other types of buried conductive lines. All such variations are contemplated as falling within the scope of the present application. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”

1. An integrated circuit, comprising:
a conductive line that is arranged in a groove, the groove being disposed in a semiconductor body; and
an insulating material that is disposed over the conductive line, wherein the insulating material comprises:
a first insulating layer comprising a horizontal portion; and
a second insulating layer and disposed over the first insulating layer.

2. The integrated circuit of claim 1,
wherein the first insulating layer has a composition that is different from a composition of the second insulating layer.

3. The integrated circuit of claim 1,
wherein the first insulating layer is formed by a method that is different from a method used to form the second insulating material.

4. The integrated circuit of claim 1, further comprising:
a gate insulating layer along sidewalls of the groove and arranged to separate the conductive line from the semiconductor body.

5. The integrated circuit of claim 4, wherein the conductive line comprises:
a conductive filling arranged in the groove, and
a first conductive layer disposed between the conductive filling and the gate insulating layer.

6. The integrated circuit of claim 5, wherein the first insulating layer is disposed on the first conductive layer without covering the conductive filling.

7. The integrated circuit of claim 1, further comprising:
a protective liner formed over at least partially over the insulating material.

8. An integrated circuit comprising:
a groove disposed in a semiconductor body;
a conductive line that is arranged in the groove, the conductive line comprising: a first conductive layer disposed on sidewalls of the groove, and a conductive filling over the first conductive layer; and
an insulating material that is disposed over the conductive line, the insulating material comprising: a first insulating layer that is disposed on the first conductive layer; and a second insulating layer.

9. The integrated circuit of claim 8, wherein the first insulating layer is disposed on the first conductive layer without covering an upper surface of the conductive filling.

10. The integrated circuit of claim 9, wherein the second insulating layer abuts both the upper surface of the conductive filling and an upper surface of the first insulating layer.

11. The integrated circuit of claim 8, further comprising:
a gate insulating layer along the sidewalls of the groove and arranged to separate the conductive line from the semiconductor body.

12. A method of forming an integrated circuit, comprising:
forming a groove in a semiconductor body;
forming a gate dielectric layer on sidewalls of the groove;
forming a conductive line in the groove over the gate dielectric layer;
forming a first insulating layer in the groove over the conductive line; and
forming a second insulating layer in the groove over the first insulating layer.

13. The method of claim 12,
wherein the first insulating layer has a composition that is different from a composition of the second insulating layer.

14. The method of claim 12,
wherein the first insulating layer is formed by a method that is different from a method used to form the second insulating layer.

15. The method of claim 12, wherein forming the conductive line comprises:
forming a first conductive layer on sidewalls of the groove, and
forming conductive filling over the first conductive layer.

16. The method of claim 15, wherein the first conductive layer has a composition that is different from a composition of the conductive filling.

17. The method of claim 12, wherein forming the first and second insulating layers comprises:
forming the first insulating layer;
partially removing the first insulating layer; and
forming the second insulating layer of the partially removed first insulating layer.

18. The method of claim 12, further comprising:
forming a protective liner at least partially over the second insulating layer.

19. A method of forming an integrated circuit, comprising:
forming a groove in a semiconductor body;
forming a first conductive layer on sidewalls of the groove;
forming a conductive filling in the groove over the first conductive layer; and
forming an insulating material in the groove over the first conductive layer.

20. The method of claim 19, wherein forming the insulating material comprises:
forming a first insulating layer on the first conductive layer; and
forming a second insulating layer on the first insulating layer.

21. The method of claim 20, where the first insulating material comprises Tetra Ethyl Oxysilane (TEOS), and the second insulating layer has a different composition than the first insulating material.

22. The method of claim 20, wherein the first insulating layer is disposed on the first conductive layer without covering an upper surface of the conductive filling.

23. The method of claim 22, wherein the second insulating layer abuts both the upper surface of the conductive filling and an upper surface of the first insulating layer.

24. The method of claim 20, further comprising:
forming a protective liner at least partially over the second insulating layer; and
forming a conductive layer over the protective liner; and
forming upper level interconnect over the conductive layer.

25. A memory device, comprising:
a plurality of memory cells associated with a semiconductor body, each of the memory cells comprising: a storage element and an access transistor;
a plurality of active area lines and a plurality of isolation trenches that extend along a first direction of the semiconductor body, the isolation trenches being adjacent to the active area lines such that each isolation trench is disposed between and electrically isolates a first active area line from a second active area line;
a plurality of buried wordlines disposed in respective grooves in the semiconductor body and extending along a second direction that differs from the first direction, each buried wordline coupled to a row of memory cells and adapted to selectively electrically couple corresponding storage elements to corresponding bit lines, and each buried wordline having an insulating material that is disposed in the groove over that buried wordline, the insulating material comprising: a first insulating layer, and a second insulating layer.

26. The memory device of claim 25, wherein a gate insulating layer separates each buried wordline from the semiconductor body, and where each buried wordline further comprises:
a conductive filling, and
a first conductive layer disposed between the conductive filling and the gate insulating layer.

27. A memory device, comprising:
a groove disposed in a semiconductor body;
a conductive line arranged in the groove;
an insulating material arranged in the groove and disposed over the conductive line; and
a protective liner at least partially over the insulating layer.

28. The memory device of claim 27, wherein the insulating material comprises:
a first insulating layer comprising a horizontal portion; and
a second insulating layer and disposed over the first insulating layer.

29. The memory device of claim 27, where conductive line comprises:
a first conductive layer disposed on sidewalls of the groove, and
a conductive filling over the first conductive layer.

30. The memory device of claim 27, further comprising:
a conductive layer abutting a top surface of the protective liner; and
upper level interconnect over the conductive layer.

31. The memory device of claim 27, wherein the protective liner comprises an insulating material.

32. The memory device of claim 27, wherein the protective liner comprises Tetra Ethyl Oxysilane (TEOS).
